(19) United States
(12) Patent Application Publication
(10) Pub. No.: US 2026/0369329 A1
(43) Pub. Date: Nov. 19, 2026

(54) MEMORY SYSTEM AND METHOD OF IDENTIFYING BAD BLOCK THEREOF

(71) Applicant: SK hynix Inc., Gyeonggi-do (KR)

(72) Inventor: Ji Hyun LEE, Gyeonggi-do (KR)

(21) Appl. No.: 19/466,518

(22) Filed: Feb. 2, 2026

(30) Foreign Application Priority Data
May 14, 2025 (KR) 10-2025-0062595

(51) Int. Cl. G11C 16/28; G11C 16/08; G11C 29/02

(52) U.S. Cl. CPC G11C 16/28; G11C 16/08; G11C 29/022

(57) ABSTRACT

The present disclosure relates to a memory system. The memory system includes a memory device including a plurality of memory blocks, and a memory controller configured to control the memory device to perform a read operation on a selected memory block of the plurality of memory blocks, receive read data in response to the read operation, the read data indicating a logic value of each of memory cells included in the selected memory block, and determine the selected memory block as an initial bad block in response to the read data indicating the logic value of each of the memory cells as a predefined value .

### CROSS-REFERENCE TO RELATED APPLICATION

The present application claims priority under 35 U.S.C. § 119(a) to Korean patent application number 10-2025-0062595 filed on May 14, 2025, the entire disclosure of which is incorporated by reference herein.

### BACKGROUND

### 1. Technical Field

Various embodiments relate generally to a memory system, and more particularly, to a memory system and a method of identifying whether a memory block included in a memory device is bad based on a result of reading the memory block.

### 2. Related Art

A memory device is divided into a volatile memory and a non-volatile memory. A volatile memory is a memory device that stores data only when power is supplied, and when the power supply is cut off, the stored data is destroyed. A non-volatile memory is a memory device in which data is not destroyed even when the power is cut off.

A memory device includes a plurality of memory blocks. The plurality of memory blocks may include a bad block. The memory device cannot perform a program operation on the bad block, and a memory controller needs to determine whether memory blocks are available for utilization. The memory device stores information about whether a memory block is a bad black in a system block that stores system data. However, errors may occur in a system block, and the resources of the system block may be limited. Thus, a separate method of identifying a bad block may be needed.

### SUMMARY

Embodiments of the present disclosure provide a memory system and a method of identifying a bad block by determining whether a memory block is an initial bad block based on read data of a read operation performed on a selected memory block among a plurality of memory blocks.

According to an embodiment, a memory system may include a memory device including a plurality of memory blocks, and a memory controller configured to control the memory device to perform a read operation on a selected memory block of the plurality of memory blocks, receive read data in response to the read operation, the read data indicating a logic value of each of memory cells included in the selected memory block, and determine the selected memory block as an initial bad block in response to the read data indicating the logic value of each of the memory cells as a predefined value.

According to an embodiment, a method of operating a memory system may include performing a read operation on a selected memory block of a plurality of memory blocks included in a memory device, receiving read data in response to the read operation, the read data indicating a logic value of each of memory cells included in the selected memory block, and determining the selected memory block as an initial bad block in response to the read data indicating each of the logic values of the memory cells as a predefined value.

According to an embodiment, a method of operating a memory controller controlling a memory device including a plurality of memory blocks may include selecting a memory block subject to bad block determination from the plurality of memory blocks, transferring a read command directing a read operation on the memory block to the memory device, receiving read data in response to the read operation, and determining, based on the read data, the memory block as an initial bad block in response to logic values of memory cells included in the memory block being all predefined values.

### BRIEF DESCRIPTION OF THE DRAWINGS

FIG. 1 is a diagram illustrating a memory system according to an embodiment of the present disclosure;

FIG. 2 is a diagram illustrating an operation of identifying an initial bad block according to an embodiment of the present disclosure;

FIG. 3 is a diagram illustrating a memory block according to an embodiment of the present disclosure;

FIG. 4 is a diagram illustrating threshold voltages of memory cells according to embodiments of the present disclosure;

FIG. 5 is a flowchart illustrating an operation of identifying a bad block according to an embodiment of the present disclosure; and

FIG. 6 is a diagram illustrating a data storage system including a memory system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts. The examples of embodiments in accordance with the concepts may be carried out by various forms but the descriptions are not limited to the examples of embodiments described in this specification.

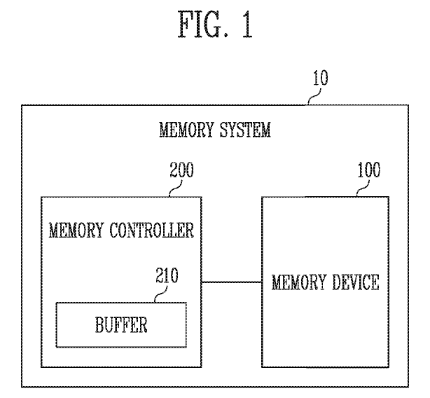

FIG. 1 is a diagram illustrating a memory system 10 according to an embodiment of the present disclosure.

Referring to FIG. 1, the memory system 10 may include a memory device 100 and a memory controller 200 which controls the operation of the memory device 100. The memory system 10 may store data under the control of a host device, such as a cell phone, a smartphone, an MP3 player, a laptop computer, a desktop computer, a gaming machine, a television, a tablet PC, or an in-vehicle infotainment system.

The memory device 100 may store data. The memory device 100 may operate in response to control from the memory controller 200. The memory device 100 may include a memory cell array including a plurality of memory cells which store data. Each of the memory cells included in the memory cell array may be a single-level cell (SLC) which stores one bit of data, or a memory cell which stores multi-bit data. A memory cell which stores multi-bit data may be a multi-level cell (MLC) storing two bits of data, a triple-level cell (TLC) storing three bits of data, a quad-level cell (QLC) storing four bits of data, or a penta-level cell (PLC) storing five bits of data, depending on the number of bits in the multi-bit data.

The memory device 100 may include a plurality of memory blocks. Each of the plurality of memory blocks may include memory cells. The memory device 100 may be configured to receive a command and an address from the memory controller 200, and to access a region of the memory cell array which is selected by the address. The memory device 100 may perform an operation instructed by the command on the region selected by the address. For example, the memory device 100 may perform a read operation, a program operation, or an erase operation on the plurality of memory cells.

The memory controller 200 may control the overall operation of the memory system 10. The memory controller 200 may control the memory device 100 to perform a program operation, a read operation, or an erase operation in response to a request from the host device. The memory controller 200 may generate a control signal to control the operation of the memory device 100.

The memory controller 200 may receive read data from the memory device 100. The memory controller 200 may determine, based on the read data, whether a memory block on which the read operation is performed is a bad block (or not a bad block). The memory controller 200 may include a buffer 210 which stores bad block information indicating whether the memory block is a bad block.

According to an embodiment of the present disclosure, the memory controller 200 may identify whether the memory block is an initial bad block based on the read data. The initial bad block may refer to a bad block which occurs during the manufacturing phase of the memory device 100. In addition to the initial bad block, the bad block may include a later bad block which occurs at the end of the lifetime of a normal memory block.

When a later bad block is detected, the memory controller 200 may increase threshold voltages of all memory cells included in the later bad block to indicate a bad block.

According to an embodiment of the present disclosure, whether a memory block is a bad block is determined based on read data of the memory block without reading bad block information stored in a system block for storing system data. Accordingly, bad block information may not be stored in the system block, and resources of the system block may be saved.

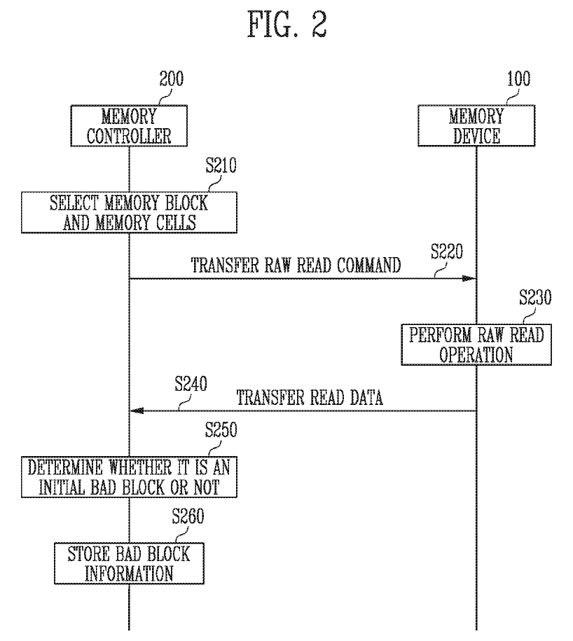

FIG. 2 is a diagram illustrating an operation of identifying an initial bad block according to an embodiment of the present disclosure.

Referring to FIG. 2, the memory controller 200 may identify whether a memory block included in the memory device 100 is a bad memory block or not, and may determine whether the memory block is available for use. The memory controller 200 may determine whether the memory block is bad based on read data for the memory block without reading bad block information stored in a system block of the memory device 100.

The memory controller 200 may select a memory block subject to initial bad block determination among the plurality of memory blocks included in the memory device 100 (S210). The memory controller 200 may select a predetermined number or more of memory cells included in the memory block, and may generate a raw read command for the selected memory cells.

According to an embodiment of the present disclosure, the accuracy of the bad block determination may increase as the number of selected memory cells increases. More specifically, when 32 memory cells are selected, an error may occur with a probability of 1/2³².

When the memory device 100 performs a read operation, the memory controller 200 may perform an error correction operation based on the read data. When the memory controller 200 detects an error in the read data, the memory controller 200 may control the memory device 100 to perform the read operation by changing a read voltage. According to an embodiment of the present disclosure, a read operation in which an error correction operation is not performed (for example, bypassed) may be a raw read operation.

The memory controller 200 may generate a raw read command which directs a raw read operation. The memory controller 200 may generate the raw read command and transfer the raw read command to the memory device 100 (S220).

The memory device 100 may perform the raw read operation in response to receiving the raw read command (S230). The memory device 100 may compare a threshold voltage of each of the selected memory cells with a reference value. The memory device 100 may return a logic high as a logic value of the memory cell when the threshold voltage of the memory cell is the reference value or greater, and may return a logic low as a logic value of the memory cell when the threshold voltage of the memory cell is less than the reference value. The memory device 100 may return a logic value for each of the selected memory cells.

According to an embodiment of the present disclosure, the reference value compared to the threshold voltage may be a midpoint of a range of the threshold voltages of the memory cells. The threshold voltage range of the memory cells may be independent of the number of bits of data stored in each of the memory cells. More specifically, the threshold voltage ranges of the SLC, MLC, TLC, QLC, and PLC may all be the same. In other words, the reference value compared to the threshold voltage of the SLC may be the same as that compared to the threshold voltage of the TLC.

The memory device 100 may transfer read data indicating a result of the raw read operation to the memory controller 200 (S240). The read data may include logic values for memory cells designated by the raw read command.

The memory controller 200 may determine, based on the read data, whether the selected memory block is an initial bad block (S250). The memory controller 200 may determine that the selected memory block is the initial bad block in response to the read data indicating that the logic values for all selected memory cells are high.

In manufacturing the memory device 100, when a bad block is detected, the memory controller 200 is programmed to fix the threshold voltages of all memory cells included in the bad block to be very high values. The threshold voltages of the memory cells are greater than a reference value used in a raw read operation, and the fixed threshold voltage may not change even when the memory device 100 performs operations on the memory blocks.

When data is stored in a memory block, it may be probabilistically impossible for the logic values of all memory cells to be stored as logic high due to data randomization, data patterns, or the like. The memory controller 200 may use logic values of at least a predetermined number or more of memory cells included in the memory block to determine whether the memory block is an initial bad block.

The memory controller 200 may store, in the buffer 210, bad block information indicating whether the memory block is bad (S260). The information indicating whether the memory block is initially bad may be stored in a system block which stores system data of the memory device 100. Conventionally, the result of performing a determination operation on the memory block and the information stored in the system block are compared to identify whether the memory block is bad.

However, errors may occur in the system block, and the system block may have limited resources due to its inherent characteristics. According to an embodiment of the present disclosure, the bad block information is not stored in the system block, and the bad block is determined based on the read data for the memory block, so that the resources of the system block may be saved.

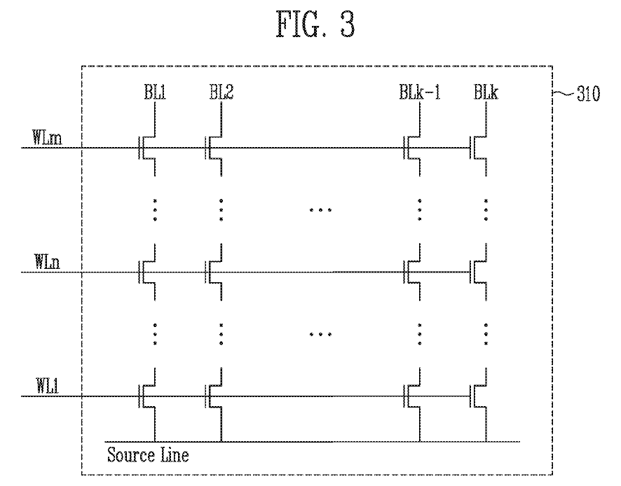

FIG. 3 is a diagram illustrating a memory block 310 according to an embodiment of the present disclosure.

Referring to FIG. 3, the memory block 310 may include a plurality of memory cells. The memory block 310 may be coupled between word lines WL1 to WLm and bit lines BL1 to Blk. In FIG. 3, it may be assumed that ‘m’ memory cells are coupled in series between a bit line and a source line, and k memory cells have gate terminals coupled via the same word line.

The memory block 310 as shown in FIG. 3 is only one example of the plurality of memory blocks included in the memory device 100, and the structure and form of the memory blocks may vary. The number of memory cells included in each of the memory blocks may so vary. The memory block 310 as shown in FIG. 3 may be a selected memory block in which a raw read operation is performed among the plurality of memory blocks included in the memory device 100.

Each of the memory cells included in the memory block may store one or more bits of data. According to an embodiment of the present disclosure, the memory controller 200 may generate a raw read command directing a raw read operation for ‘k’ memory cells coupled to an nth word line WLn. Physical addresses of the k memory cells are contiguous. The memory device 100 may transfer read data including logic values for the k memory cells to the memory controller 200. The memory controller 200 may determine whether the memory block 310 is an initial bad block, based on the read data.

For example, when all of the logic values of the k memory cells are high, the memory controller 200 may determine that the memory block 310 is an initial bad block. The memory controller 200 may store, in the buffer 210, the bad block information indicating that the memory block 310 is the initial bad block. Since the bad block information for the memory block 310 is stored in the buffer 210, system data for the memory block 310 may not be read or no additional bad block identification operations may be performed.

In another embodiment of the present disclosure, the memory controller 200 may control the memory device 100 such that a raw read operation may be performed on memory cells coupled to at least one word line. For example, the memory controller 200 may control the memory device 100 such that a raw read operation is performed on ‘2k’ memory cells coupled to an nth word line WLn and an (n+1)th word line WLn+1. The memory controller 200 may determine whether the memory block 310 is the initial bad block based on logic values of the 2k memory cells.

In another embodiment of the present disclosure, the number of memory cells on which the raw read operation is performed may vary. The memory cells on which the raw read operation is performed may be coupled via a single word line or a plurality of word lines. The number of memory cells in which the raw read operation is performed may be determined based on the size of a data chunk corresponding to the read operation performed in the memory device 100. As the number of memory cells on which the raw read operation is performed increases, the accuracy of the bad block determination of the memory controller 200 may be improved.

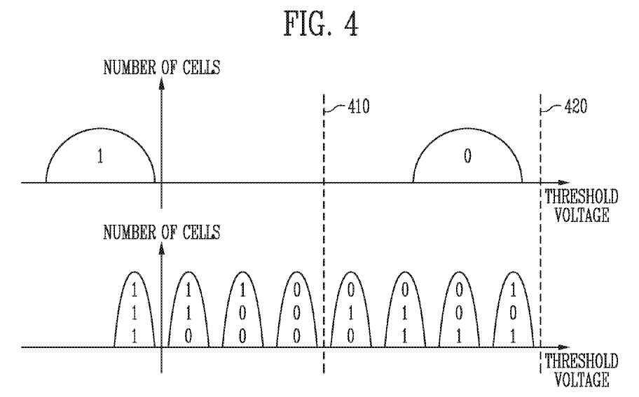

FIG. 4 is a diagram illustrating threshold voltages of memory cells according to an embodiment of the present disclosure.

Referring to FIG. 4, threshold voltage distributions according to the number of bits of data stored in one memory cell may be shown. For ease of explanation, the upper portion of FIG. 4 illustrates a threshold voltage distribution of an SLC and the lower portion of FIG. 4 illustrates a threshold voltage distribution of a TLC. While FIG. 4 shows an example of the number of bits of data stored in one memory cell, embodiments of the present disclosure may not be limited thereto. In the graph of FIG. 4, the horizontal axis represents a threshold voltage and the vertical axis represents the number of memory cells. In FIG. 4, reference voltage 410 may represent an intermediate value of a range of threshold voltages of memory cells, and reference voltage 420 may represent a threshold voltage at which threshold voltages of memory cells included in a bad block are fixed when the bad block is detected during manufacturing of the memory device 100.

When a memory cell is an SLC, a logic value of the memory cell in an erase state is low, and a logic value of the memory cell in a program state is high. The logic value for low may be 1, and the logic value for high may be 0. When the memory cell is a TLC, the logic value representing the erase state is low, as in the SLC, but there are a plurality of program states. In FIG. 4, numbers corresponding to the respective program states may vary.

According to an embodiment of the present disclosure, regardless of the number of bits stored in the memory cell, a reference value which is compared with a threshold voltage of the memory cell when a raw read operation is performed is an intermediate value of the threshold voltage range. That is, the threshold voltage is compared with reference voltage 410 regardless of whether the memory cell is the SLC or the TLC.

At the time of manufacturing the memory device 100, the threshold voltage of the bad memory cell is fixed at reference voltage 420. When the memory block selected by the memory controller 200 is an initial bad block, the threshold voltages of all memory cells included in the memory block are reference voltage 420. When the memory controller 200 compares the threshold voltages of the selected memory cells with reference voltage 410, the threshold voltages are greater than reference voltage 410, so the logic values of the memory cells are all high. The memory controller 200 may determine that the selected memory block is an initial bad block.

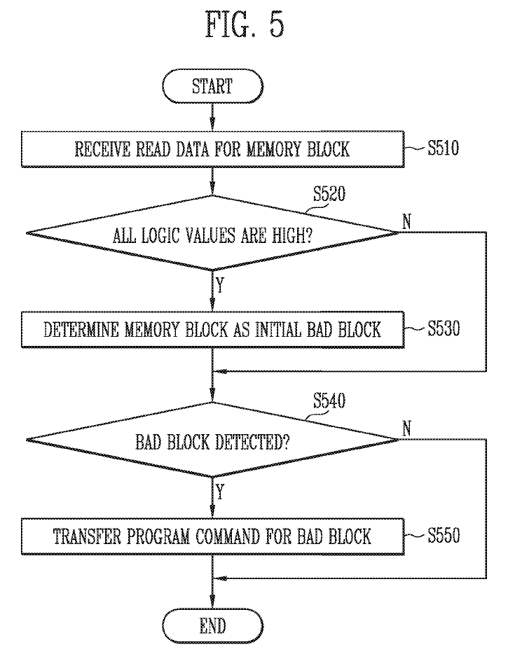

FIG. 5 is a flowchart illustrating the operation of identifying a bad block according to an embodiment of the present disclosure.

Referring to FIG. 5, a memory controller may determine whether a memory block is an initial bad block based on a result of a read operation on the memory block included in a memory device. To receive read data for the memory block, the memory controller may select one memory block of a plurality of memory blocks included in the memory device, and may generate and transfer to the memory device, a raw read command directing a raw read operation for a predetermined number or more of the memory cells included in the selected memory block. The predetermined number or more of the memory cells may be consecutive physical addresses.

At S510, the memory controller may receive the read data for the memory block from the memory device. The read data may represent a result of the raw read operation.

At S520, the memory controller may determine, based on the received read data, whether logic values of the memory cells all correspond to predetermined values (e.g., a logic high). When it is determined that the logic values of all memory cells are high (S520, Y), the memory controller may proceed to S530 to determine the selected memory block as an initial bad block. On the other hand, when it is determined that the logic values of the memory cells are not all high (S520, N), the memory controller may proceed to S540.

The logic values of the memory cells are determined based on comparisons of threshold voltages of the memory cells and a reference value. When the threshold voltages are greater than or equal to the reference value, the logic values are high. When the threshold voltages are less than the reference value, the logic values are low. According to embodiments of the present disclosure, the reference value is the midpoint of the range of the threshold voltages of the memory cells.

At S530, the memory controller may store, in a buffer, bad block information indicating that the selected memory block is the initial bad block. The bad block information stored in the buffer may be used to identify whether the memory block is available for use. According to embodiments of the present disclosure, the buffer is included in the memory controller, and the buffer is different from the system block included in the memory device.

At S540, the memory controller may determine whether a bad block was detected. For example, the memory controller may detect an unavailable bad block among the plurality of memory blocks included in the memory device. Bad blocks may include initial bad blocks and later bad blocks. The bad block detected at S540 may be a later bad block.

When it is determined that the bad block is detected (S540, Y), the memory controller may proceed to S550 and transfer, to the memory device, a program command for the bad block. In response to the program command for the bad block, the memory device may raise threshold voltages of all memory cells included in the bad block to a value greater than a predetermined voltage. The predetermined voltage may be a greater than the reference value used in S520. According to an embodiment of the present disclosure, program pulses may be applied to the memory cells until the threshold voltages of all memory cells included in the bad block are fixed at 420 of FIG. 4. When it is determined that no bad blocks are detected (S540, N), the bad block identification operation may terminate.

According to embodiments of the present disclosure, bad block information may not be stored in the system block of the memory device, which may save resources of the system block. In addition to the initial bad block, a threshold voltage may be programmed to a predetermined voltage for a later bad block, so that the bad block information may not be stored in the system block of the memory device. The memory controller may receive the read data for the memory block to identify whether the memory block is available for utilization.

According to embodiments of the present disclosure, the accuracy of the bad block identification increases as the number of memory cells included in the memory block for which a raw read operation is performed increases. For example, a minimum read unit of the memory device is 2 KB for a mobile device, and 4 KB for an SSD. For a mobile device, the probability of a bad block identification error is 1/2²⁰⁴⁸, and for an SSD, the probability of the bad block identification error is 1/2⁴⁰⁹⁶, so the probability of the error may be very small.

The description of each operation in FIG. 5 may correspond to that of FIGS. 1-4.

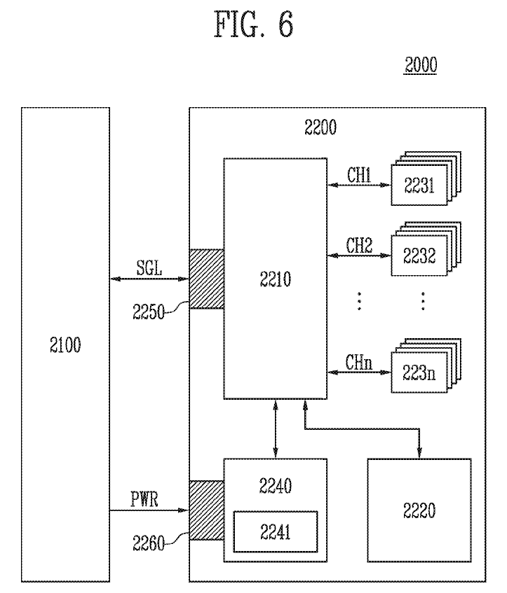

FIG. 6 is a diagram illustrating a data storage system 2000 including a memory system according to an embodiment of the present disclosure.

Referring to FIG. 6, the data storage system 2000 may include a host device 2100 and a solid state drive (SSD) 2200.

The SSD 2200 may include a controller 2210, a buffer memory device 2220, non-volatile memories 2231 to 223n, a power supply 2240, a signal connector 2250, and a power connector 2260. The SSD 2200 may include the memory device 100 described in FIGS. 1-3.

The buffer memory device 2220 may temporarily store data to be stored in the plurality of non-volatile memories 2231 to 223n. In addition, the buffer memory device 2220 may temporarily store data read from the non-volatile memories 2231 to 223n. The data temporarily stored in the buffer memory device 2220 may be transferred to the host device 2100 or the non-volatile memories 2231 to 223n in response to control of the controller 2210.

The non-volatile memories 2231 to 223n may serve as storage media of the SSD 2200. The non-volatile memories 2231 to 223n may be coupled to the controller 2210 through a plurality of channels CH1 to CHn, respectively. One or more non-volatile memories may be coupled to one channel. Non-volatile memories coupled to one channel may be coupled to the same signal bus or data bus.

The controller 2210 may perform general operations of the SSD 2200. According to an embodiment of the present disclosure, the controller 2210 may transfer a read command to the SSD 2200 so that a raw read operation may be performed on a selected memory block among a plurality of memory blocks included in the SSD 2200. The read command may include address information indicating a predetermined number or more of memory cells among memory cells included in the selected memory block. The controller 2210 may receive read data indicating a result of the raw read operation for the memory cells and determine whether the selected memory block is an initial bad block based on the read data.

The controller 2210 may determine the selected memory block as an initial bad block in response to the read data indicating that logic values of the memory cells are all high. The controller 2210 may store the bad block information indicating whether the memory blocks are bad in a buffer included in the controller 2210. The controller 2210 may control the SSD 2200 to perform a program operation to increase the threshold voltages of all memory cells included in the memory block which is determined to be a later bad block among the memory blocks.

According to an embodiment of the present disclosure, resources of the system block may be saved by performing a read operation to identify whether a memory block is bad, rather than storing bad block information indicating whether the memory block is bad in the system block.

The power supply 2240 may provide power PWR which is input via the power connector 2260 to the SSD 2200 internally. The power supply 2240 may include an auxiliary power supply 2241. The auxiliary power supply 2241 may provide power to allow the SSD 2200 to shut down normally in the event of a sudden power off. The auxiliary power supply 2241 may include large capacitors capable of charging the power PWR.

The controller 2210 may communicate a signal SGL to and from the host device 2100 via the signal connector 2250. The signal SGL may include commands, addresses, data, etc. The signal connector 2250 may be configured as various types of connectors depending on how the host device 2100 and the SSD 2200 interface.

According to the present disclosure, a memory system and a method of identifying a bad block by determining whether a memory block is an initial bad block based on read data of a read operation performed on a selected memory block among a plurality of memory blocks.

It will be apparent to those skilled in the art that various modifications can be made to the above-described embodiments of the present disclosure without departing from the spirit or scope of the invention. Thus, it is intended that the present invention cover all such modifications provided they come within the scope of the appended claims and their equivalents.

What is claimed is:

1. A memory system, comprising:
a memory device including a plurality of memory blocks; and
a memory controller configured to;
control the memory device to perform a read operation on a selected memory block of the plurality of memory blocks,
receive read data in response to the read operation, the read data indicating a logic value of each of memory cells included in the selected memory block, and
determine the selected memory block as an initial bad block in response to the read data indicating the logic value of each of the memory cells as a predefined value.

2. The memory system of claim 1, wherein the read operation includes a raw read operation in which no error correction operation is performed, and
wherein the memory controller is configured to transfer, to the memory device, a raw read command directing the raw read operation.

3. The memory system of claim 2, wherein each of the memory cells includes a data storage memory cell storing at least one bit of data, and
wherein the memory device is configured to perform the raw read operation by returning, to the memory controller, a logic high value of the memory cell when a threshold voltage of the data storage memory cell exceeds a reference value.

4. The memory system of claim 3, wherein the reference value corresponds to a midpoint of a range of threshold voltages of the memory cells.

5. The memory system of claim 1, wherein the memory controller is further configured to:
control the memory device to perform the read operation for selected memory cells having consecutive physical addresses among the memory cells; and
determine, based on read data for the selected memory cells, whether the selected memory block is the initial bad block.

6. The memory system of claim 5, wherein a number of selected memory cells is greater than or equal to a predetermined number.

7. The memory system of claim 5, wherein the memory cells are coupled via a plurality of word lines, and
wherein the memory controller is further configured to transfer, to the memory device, a read command directing the read operation for the selected memory cells coupled via at least one word line of the plurality of word lines.

8. The memory system of claim 1, wherein the memory controller includes a buffer memory storing bad block information indicating whether the selected memory block is the initial bad block.

9. The memory system of claim 1, wherein the memory controller is configured to detect an unusable bad block among the plurality of memory blocks, and transfer, to the memory device, a transient program command for the unusable bad block, and
wherein the memory device is configured to raise threshold voltages of all memory cells included in the unusable bad block to a predetermined voltage or higher in response to the transient program command.

10. A method of operating a memory system, the method comprising:
performing a read operation on a selected memory block of a plurality of memory blocks included in a memory device;
receiving read data in response to the read operation, the read data indicating a logic value of each of memory cells included in the selected memory block; and
determining the selected memory block as an initial bad block in response to the read data indicating each of the logic values of the memory cells as a predefined value.

11. The method of claim 10, wherein each of the memory cells includes a data storage memory cell storing at least one bit of data, and
wherein the performing the read operation comprises:
generating a raw read command directing a raw read operation in which no error correction operation is performed; and
returning a high logic value of the data storage memory cell when a threshold voltage of the memory cell exceeds a reference value.

12. The method of claim 11, wherein the reference value corresponds to a midpoint of a range of threshold voltages of the memory cells.

13. The method of claim 11, wherein the generating the raw read command comprises selecting a predetermined number or more of selected memory cells from the memory cells.

14. The method of claim 13, wherein the selected memory cells have consecutive physical addresses.

15. The method of claim 11, wherein the memory cells are coupled via a plurality of word lines, and
wherein the generating the raw read command comprises selecting selected memory cells coupled via at least one word line of the plurality of word lines as a target of the raw read operation.

16. The method of claim 13, wherein the determining the selected memory block as the initial bad block comprises determining, based on read data for the selected memory cells, whether the selected memory block is the initial bad block.

17. The method of claim 10, further comprising storing, in a buffer memory, bad block information indicating that the selected memory block is the initial bad block.

18. The method of claim 10, further comprising:
detecting an unusable bad block among the plurality of memory blocks; and
raising threshold voltages of all memory cells included in the unusable bad block to a value greater than a predetermined voltage.

19. The method of claim 18, wherein the predetermined voltage is greater than or equal to a midpoint of a range of threshold voltages of the memory cells.

20. A method of operating a memory controller controlling a memory device including a plurality of memory blocks, the method comprising:
selecting a memory block subject to bad block determination from the plurality of memory blocks;
transferring a read command directing a read operation on the memory block to the memory device;
receiving read data in response to the read operation; and
determining, based on the read data, the memory block as an initial bad block in response to logic values of memory cells included in the memory block being all predetermined values.

21. The method of claim 20, wherein the transferring the read command comprises:
selecting a predetermined number or more of selected memory cells having consecutive physical addresses among the memory cells; and
generating a raw read command directing a raw read operation in which no error correction operation is performed on the selected memory cells.

22. The method of claim 21, wherein each of the memory cells includes a data storage memory cell storing at least one bit of data, and
wherein the raw read operation includes an operation of returning a logic high value of the memory cell when a threshold voltage of the memory cell exceeds a midpoint of a range of threshold voltages of the memory cells.
